(19) United States
(12) Patent Application Publication
(10) Pub. No.: US 2024/0322033 A1
(43) Pub. Date: Sep. 26, 2024

(54) VERTICAL POWER TRANSISTOR

(71) Applicant: Robert Bosch GmbH, Stuttgart (DE)

(72) Inventors: Dragos Costachescu, Reutlingen (DE); Neil Davies, Sonnenbuehl-Genkingen (DE)

(21) Appl. No.: 18/255,760

(22) PCT Filed: Dec. 2, 2021
(86) PCT No.: PCT/EP2021/083865

§ 371 Date: Jun. 26, 2023

(30) Foreign Application Priority Data
Dec. 4, 2020 (DE) 10 2020 215 331.0

(51) Int. Cl. H01L 29/78; H01L 29/10; H01L 29/40; H01L 29/417

(52) U.S. Cl. CPC H01L 29/7813; H01L 29/1095; H01L 29/402; H01L 29/41725

(57) ABSTRACT

A vertical power transistor having front and rear sides. The vertical power transistor includes a drift region that includes a first doping with a first charge carrier type, and a body region that includes a second doping with a second charge carrier type. The body region is situated on the drift region, and includes trenches that extend, starting from the front side, essentially perpendicularly into the drift region. First and second areas are situated between the trenches. The first areas are situated centrally between the trenches, and the second areas are situated between the first areas and the trenches. The first and second areas, starting from the body region, extend essentially perpendicularly into the drift region. The first areas include a third doping with the second charge carrier type, and the second areas include the first doping with the first charge carrier type.

### FIELD

The present invention relates to a vertical power transistor.

### BACKGROUND INFORMATION

Vertical power transistors, in particular so-called power trench MOS field effect transistors, are preferably used as electronic switches in the automotive, industrial, entertainment, and consumer electronics sectors. The power transistors may include field plates to improve the electric strength and reduce the on-resistance. In each case a field plate is situated in a trench of the power transistor, which extends far into the drift region. This facilitates the removal of the charge carriers in the blocking case, so that the doping in the drift region may be greatly increased.

It is disadvantageous that the doping of the drift region in order to minimize the drift region resistance cannot be infinitely increased without having an adverse effect on the breakdown voltage, since the greater the doping in the drift region, the greater is the field strength at the body diode, and the lower is the breakdown voltage.

An object of the present invention is to overcome these disadvantages.

### SUMMARY

According to the present invention, a vertical power transistor is provided which includes a front side and a rear side, the front side being situated opposite from the rear side. According to an example embodiment of the present invention, in addition, the vertical power transistor includes a drift region including a first doping of a first charge carrier type, and a body region including a second doping of a second charge carrier type, the body region being situated on the drift region. The vertical power transistor includes trenches that extend, starting from the front side, essentially perpendicularly into the drift region. According to an example embodiment of the present invention, first areas and second areas are situated between the trenches, the first areas being situated centrally between the trenches, and the second areas being situated between the first areas and the trenches. In other words, the second areas extend laterally between the first areas and the trenches. The first areas and the second areas, starting from the body region, extend essentially perpendicularly into the drift region. The first areas include a third doping with the second charge carrier type, and the second areas include the first doping with the first charge carrier type. The second doping and the third doping are different. In other words, the second doping is greater or less than the third doping.

An advantage is that the breakdown strength is very high, so that the power transistor may be used in high-voltage areas.

In one refinement of the present invention, the third doping within the first areas has a gradual profile, the third doping, starting from the body region, decreasing in the direction of the drift region.

It may be advantageous that the electrical field distribution is homogenized, so that electrical field peaks are kept away from the body diode.

In a further embodiment of the present invention, a field plate is situated within each trench.

An advantage is that a very high breakdown voltage, and at the same time a very low on-resistance, are provided.

In one refinement of the present invention, the first areas have a first depth that corresponds to a second depth of the trenches in the drift region. In other words, the first areas have the same depth as the trenches.

According to an example embodiment of the present invention, it is advantageous that electrical field peaks are kept away from the active area of the power transistor.

In a further embodiment of the present invention, the first charge carrier type is n and the second charge carrier type is p.

In one embodiment of the present invention, the first areas each have a first width and the second areas each have a second width, the ratio of the first width to the second width being in the range of 0.1 to 10.

An advantage is that a large number of degrees of freedom are present for optimizing the component design.

In a further embodiment of the present invention, the ratio of an average value of the third doping to an average value of the first doping is in the range of 0.1 to 10.

It is advantageous that the breakdown strength remains high.

Further advantages result from the disclosure herein.

### BRIEF DESCRIPTION OF THE DRAWINGS

The present invention is explained below with reference to preferred embodiments and the figures.

FIG. 1 shows a vertical power transistor from the related art.

FIG. 2 shows a vertical power transistor according to the an example embodiment of the present invention.

FIG. 3 shows a comparison of the electrical field distribution of a vertical power transistor from the related art and a vertical power transistor according to an example embodiment of the present invention.

FIG. 4 shows a method for manufacturing a vertical power transistor, according to an example embodiment of the present invention.

### DETAILED DESCRIPTION OF EXAMPLE EMBODIMENTS

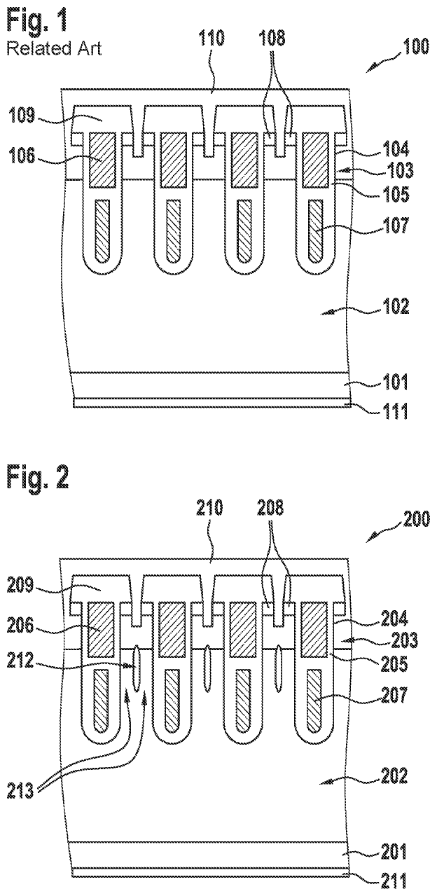

FIG. 1 shows an example of a vertical power transistor 100 that includes four active transistor cells from the related art. Vertical power transistor 100 includes a highly n-doped semiconductor substrate 101, an n-doped drift region 102, and a p-doped body region 103. Vertical power transistor 100 includes a trench structure or a plurality of trenches 104 that extend (s) into drift region 102. An oxide layer 105 is situated on the surface of the trenches. Within each trench 104, a field plate 107 is situated in each case in the lower area, and a gate electrode 106 is situated above field plate 107. Oxide layer 105 is thicker in the area of field plate 107 than in the area of gate electrode 106, oxide layer 105 insulating field plate 107 and gate electrode 106 from one another. Gate electrodes 106 are electroconductively connected to one another, and are attached to a gate contact, not illustrated. Field plates 107 are electroconductively connected to one another, and are attached to a source contact. Oxide layer 105 preferably includes SiO₂. Gate electrode 106 and also field plate 107 include polycrystalline silicon having high n-doping. Source electrodes 108 are situated on body region 103. A dielectric layer 109, for example a CVD oxide layer, is situated on source electrodes 108. A metal layer 110 that electrically contacts source electrodes 108 and body regions 103 is situated on dielectric layer 109. For better contacting, metal layer 110 includes contact trenches, which with source electrodes 108 and body regions 103 form ohmic contacts. Metal layer 110 includes aluminum, for example. A metal layer that functions as a drain electrode 111 is situated below semiconductor substrate 101.

When a voltage is present between the drain contact and the source contact, a space charge region thus forms at a body diode, the space charge region being situated at the transition between body region 103 and drift region 102, and at the MOS structure, the transition to field plate 107, oxide layer 105, and drift region 102. This space charge region extends into drift region 102 to below trench structure 104. The electrical field peaks are shifted in the direction of the trench base, in particular up to a base of field plates 107.

FIG. 2 shows a vertical power transistor 200 according to the present invention. Vertical power transistor 200 includes a semiconductor substrate 201 on which a drift region 202 is situated. Drift region 202 includes a first doping with a first charge carrier type. A body region 203 is situated on drift region 202. Body region 203 includes a second doping with a second charge carrier type. Source areas 208 are situated on body region 203. A metal layer that functions as a drain contact or drain electrode 211 is situated below semiconductor substrate 201. Vertical power transistor 200 includes a front side and a rear side, the front side being situated opposite from the rear side. The rear side is the side on which drain electrode 211 is situated. Starting from the front side, a trench structure or a plurality of trenches 204 extend (s) into drift region 202. An oxide layer 205 is situated on the trench surface. Each trench 204 includes a field plate 207 and a gate electrode 206, gate electrode 206 being situated above field plate 207 and electrically insulated from field plate 207 with the aid of oxide layer 205. Oxide layer 205 is thicker in the area of field plate 207 than in the area of gate electrode 206. A dielectric layer 209, for example a CVD oxide layer, is situated on source areas 208. A metal layer 210 that electrically contacts source areas 208 and body regions 203 is situated on dielectric layer 209. First areas 212 and second areas 213 are situated between trenches 204. First areas 212 are essentially centrally situated between trenches 204. Second areas 213 are laterally situated between first areas 212 and trenches 204. First areas 212 and second areas 213, starting from body region 203, extend essentially perpendicularly in the direction of or into drift region 202. In other words, first areas 212 and second areas 213 directly adjoin body region 203. First areas 212 include a third doping with the second charge carrier type, and second areas 213 include the first doping with the first charge carrier type. The second doping and the third doping are different. In other words, vertical power transistor 200 has a compensation structure according to the super junction principle. Columns with first and third doping are laterally situated in alternation between trenches 204, in the epitaxial layer or in drift region 202. The columns act as micro super junction structures. This reduces the field strength at the body diode, so that the space charge region extends to below the trench bases. The electrical field thus has a rectangular profile.

The first doping has dopant concentrations between 1e16 1/cm³ and 5e17 1/cm³. The second doping has a dopant concentration of 2e17 1/cm³, for example, and the third doping has a dopant concentration of approximately 0.9e17 1/cm³, for example. Within first areas 212, the third doping may have a gradual profile, for example −1e17 1/μm. The ratio of the average values or mean values of the third doping to the first doping is between 0.1 and 10.

First areas 212 have a first width and a first depth. Second areas 213 have a second width. The first width and the second width have a ratio between 0.1 and 10. This ratio is a function of the selection of further parameters that have an influence on the electric strength or the on-resistance of vertical power transistor 200. These parameters include, for example, the depth of trenches 204 and the oxide thickness in the area of field plates 207. Semiconductor material 201 is silicon, for example.

The first depth, starting from the transition between body region 203 and drift region 202, extends down to a depth of the trench bases. In other words, first areas 212 have the same depth as trench structure 204.

In one exemplary embodiment, the first charge carrier type is n and the second charge carrier type is p. In a further exemplary embodiment, the first charge carrier type is p and the second charge carrier type is n.

Vertical power transistors 200 may find application in the electric drive train, for example in the DC/DC converter or in the inverter, of electric vehicles or hybrid vehicles. Vertical power transistors may likewise find application in motor vehicle charging devices or in inverters of home appliances.

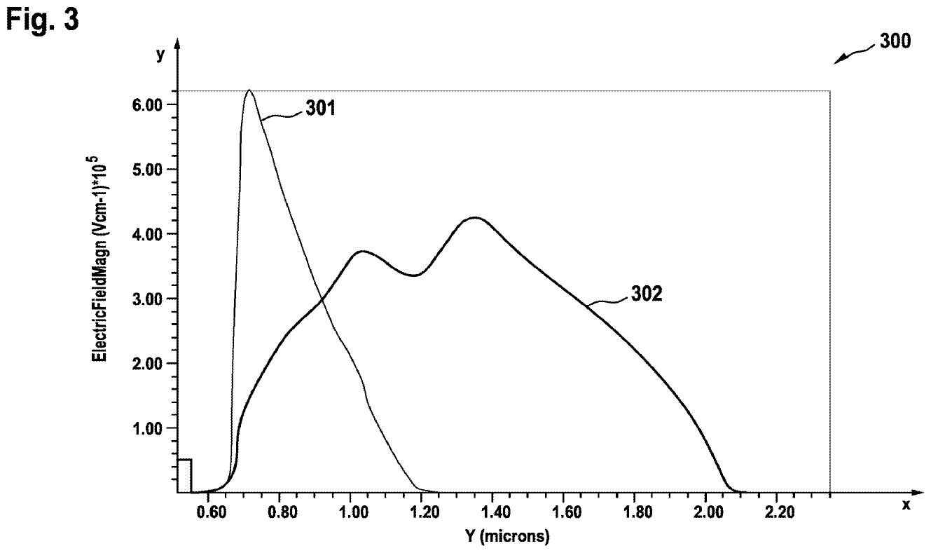

FIG. 3 shows a comparison of electrical field distribution 300 of a vertical power transistor from the related art and a vertical power transistor according to the present invention. The depth of the drift region, starting from the body region in the direction of the semiconductor substrate, is illustrated in μm on the x axis, and the electrical field strength in 10\hat{ }5 V/cm is illustrated on the y axis. Curve 301 shows the electrical field distribution of the vertical power transistor from FIG. 1, and curve 302 shows the electrical field distribution of a vertical power transistor according to the present invention for the case that the dopant concentrations in drift regions 102 and 202 have the same value.

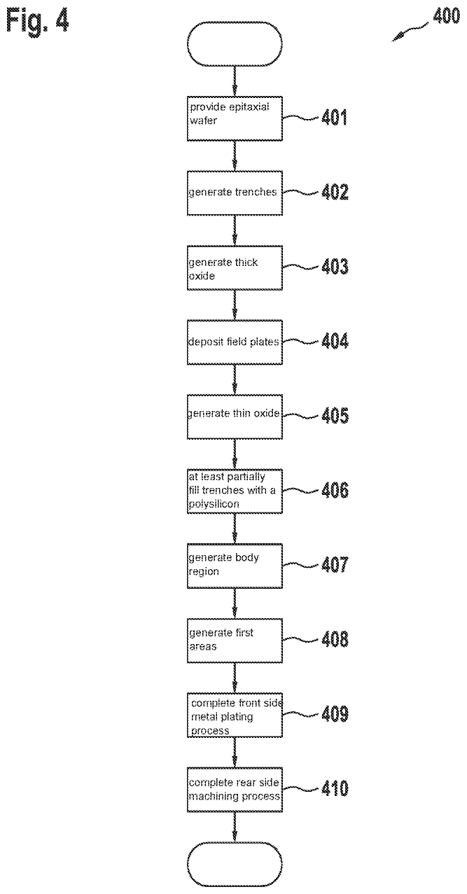

FIG. 4 shows a method 400 for manufacturing a vertical power transistor. The method starts with a step 401 in which an epitaxial wafer is provided. A plurality of trenches is generated with the aid of anisotropic plasma etching in a subsequent step 402. A thick oxide is generated within the trenches in a subsequent step 403. Field plates are deposited on the thick oxide in a subsequent step 404. A thin oxide is generated on the field plates and the side walls of the trenches in a subsequent step 405. The trenches are at least partially filled with a polysilicon in a subsequent step 406, resulting in gate electrodes. The body region is generated with the aid of boron ion implantation and the second areas are generated with the aid of phosphorous ion implantation in a subsequent step 407. The first areas are generated in a subsequent step 408 with the aid of multiple boron ion implantations with different implantation energies and implantation doses. The front side metal plating process is completed in a subsequent step 409. The rear side machining process according to the related art is completed in a subsequent step 410.

1-7. (canceled)

8. A vertical power transistor, comprising:
a front side and a rear side, the front side being situated opposite from the rear side;
a drift region that includes a first doping with a first charge carrier type;
a body region that includes a second doping with a second charge carrier type, the body region being situated on the drift region;
trenches that extend, starting from the front side, perpendicularly into the drift region; and
first areas and second areas are situated between the trenches, the first areas being situated centrally between the trenches, and the second areas being situated between the first areas and the trenches, the first areas and the second areas, starting from the body region, extending perpendicularly into the drift region, the first areas including a third doping with the second charge carrier type, and the second areas including the first doping with the first charge carrier type, the second doping and the third doping being different.

9. The vertical power transistor as recited in claim 8, wherein the third doping within the first areas has a gradual profile, the third doping, starting from the body region, decreasing in a direction of the drift region.

10. The vertical power transistor as recited in claim 8, wherein a field plate is situated within each of the trenches.

11. The vertical power transistor as recited in claim 8, wherein the first areas have a first depth that corresponds to a second depth of the trenches in the drift region.

12. The vertical power transistor as recited in claim 8, wherein the first charge carrier type is n and the second charge carrier type is p.

13. The vertical power transistor as recited in claim 8, wherein each of the first areas has a first width and each of the second areas has a second width, a ratio of the first width to the second width being in a range of 0.1 to 10.

14. The vertical power transistor as recited in claim 8, wherein a ratio of an average value of the third doping to an average value of the first doping is in a range of 0.1 to 10.
